(19) United States
(12) Patent Application Publication
(10) Pub. No.: US 2021/0313358 A1
(43) Pub. Date: Oct. 7, 2021

(54) PHOTODIODE AND MANUFACTURING METHOD, SENSOR AND SENSING ARRAY

(71) Applicant: NINGBO ABAX SENSING CO., LTD., Ningbo, Zhejiang (CN)

(72) Inventor: Shuyu LEI, Xi'an, Shaanxi (CN)

(73) Assignee: NINGBO ABAX SENSING CO., LTD., Ningbo, Zhejiang (CN)

(21) Appl. No.: 17/269,917

(22) PCT Filed: Aug. 20, 2018
(86) PCT No.: PCT/CN2018/101273

§ 371 Date: Feb. 19, 2021

(51) Int. Cl. H01L 27/146; G01S 17/08

(52) U.S. Cl. CPC H01L 27/1461; G01S 17/08; H01L 27/14689; H01L 27/14643

(57) ABSTRACT

Provided are a photodiode and a manufacturing method, a sensor and a sensor array. The photodiode comprises: a semiconductor substrate; an epitaxial layer formed on the semiconductor substrate; and a photodiode region formed in a pre-determined region of the epitaxial layer and used for generating photo-generated carriers, wherein the photodiode region comprises at least two doped regions, and the doped regions of different potentials from among the at least two doped regions are arranged from the edge of the photodiode region to the geometric center of the photodiode region. By means of the photodiode, photo-generated carriers randomly distributed in a photodiode region are first concentrated at a specified position and then reach a transmission gate through the specified position, thereby significantly improving the response speed and measurement accuracy of the photodiode.

### TECHNICAL FIELD

Embodiments of the present disclosure relate to the technical field of microelectronics. More specifically, the embodiments of the present disclosure relate to photodiodes, methods of fabricating the same (a manufacturing method), sensors, and sensor arrays (or a sensing array).

### BACKGROUND ART

Complementary metal oxide semiconductor (CMOS) sensors attract great attention due to its low cost and better suitability for mass production; such as commonly used CMOS sensors include CMOS sensors based on photodiode structures, and the like. In scenario of measuring a long distance and with high-precision, since light travels fast, a CMOS sensor is required to have a high response speed and high precision, for example, a CMOS sensor is required to have a response time of tens of nanoseconds, so that to make sure the CMOS sensor being able to receive reflected radiation in time.

In a prior art photodiode structure such as a 4T structure shown in FIG. 1, multiple transmission gates (TX) are arranged on one end of a photodiode. Once the multiple transmission gates are turned on, a larger potential difference is created between the photodiode and parts under the gates, so that photogenerated carriers are attracted to move to the parts under the gates. However, since the transverse potential in the photodiode structure scarcely changes, diffusion remains the major way for the photogenerated carriers to travel. This results in a slow speed of transmission of the photogenerated carriers, and in turn leads to a slow response speed and poor precision of the CMOS sensor. Since the multiple transmission gates are arranged on one end of the photodiode, the photogenerated carriers thus travel a long transmission path from the other end of the photodiode to the parts under the gates, which causes a long delay in the transmission of the photogenerated carriers and leads to a slow response speed and poor precision of the CMOS sensor. In addition, the photogenerated carriers travel different paths to the different transmission gates, the photogenerated carriers thus travel with different delays, which thereby leads to systematic errors.

In summary, the CMOS sensors based on the prior art photodiode structures are far from satisfying the requirements for sensors used for measuring long distance and with high-precision.

### SUMMARY

The CMOS sensors based on the prior art photodiode structures are far from satisfying the requirements for CMOS sensors in measuring long distance with high precision, due to the slow response speed and poor precision as well as systematic errors of the prior art photodiode structures. Therefore, it is urgent to design an improved photodiode structure to solve the above-mentioned technical problems. In this context, the embodiments of the present disclosure are expected to provide a photodiode, a method of fabricating the same, a sensor, and a sensor array.

In a first aspect of the embodiments of the present disclosure, a photodiode is provided. The photodiode includes: a semiconductor substrate; an epitaxial layer formed on the semiconductor substrate; a photodiode region formed in a predetermined region of the epitaxial layer and configured to generate photogenerated carriers. The photodiode region includes at least two doped regions. Doped regions with different potentials among the at least two doped regions are arranged in a direction from an edge of the photodiode region to a geometric center of the photodiode region. In an embodiment of the present disclosure, the geometric center of the photodiode region is the geometric center of a surface of the photodiode region.

It can be seen from the above description that in the photodiode according to the first aspect, the photogenerated carriers are attracted to move along the direction towards the geometric center of the photodiode region 320 from the edge of the photodiode region, so that the photogenerated carriers randomly distributed in the photodiode region 320 are firstly concentrated in a specified position and then transferred to transmission gates from the specified position, thereby avoiding systematic errors resulting from different transmission delays caused by these randomly distributed photogenerated carriers travelling different paths to reach different transmission gates. This contributes to an improved measurement precision of a sensor. Also, this avoids a longer transmission delay resulting from some photogenerated carriers are farther from the transmission gates than other photogenerated carriers. This helps shorten the delay of transmission of the photogenerated carriers to parts under the gates and increase the speed of transmission of the photogenerated carriers and the response speed of the sensor.

In an embodiment of the present disclosure, different doped regions among the at least two doped regions have different doping concentrations and/or, different doped regions among the at least two doped regions have different body zone widths.

In an embodiment of the present disclosure, the shape of the predetermined region is a geometric figure symmetric about the geometric center.

Correspondingly, in an embodiment of the present disclosure, the formation of different doped regions among the at least two doped regions with different doping concentrations includes a case where: if the at least two doped regions are N-type doped regions, the concentration of an N-type material in a doped region with a low potential is greater than the concentration of the N-type material in a doped region with a high potential; or if the at least two doped regions are P-type doped regions, the concentration of a P-type material in the doped region with a low potential is less than the concentration of the P-type material in the doped region with a high potential; or if the at least two doped regions are N-type doped regions, the concentration of a P-type material in the doped region with a low potential is not greater than the concentration of the P-type material in the doped region with a high potential; or if the at least two doped regions are P-type doped regions, the concentration of an N-type material in the doped region with a high potential is not greater than the concentration of the N-type material in the doped region with a low potential.

The doping concentrations in different doped regions among the at least two doped regions are adjusted so that the different doped regions among the at least two doped regions have different potentials, which contributes to the formation of a modulated electric field with a certain potential gradient in the photodiode region, thereby increasing the speed of transmission of the photogenerated carriers. Also, this helps eliminate an effect of crowding of electrons at the edge caused by the narrowing of the body zone width of a doped region, thereby further decreasing the potential of the doped region.

Correspondingly, in an embodiment of the present disclosure, the formation of different doped regions among the at least two doped regions with different body zone widths includes a case where: different doped regions among the at least two doped regions have different body zone widths, where in different doped regions with an identical concentration of a doping material, a doped region with a low potential has a body zone width larger than a body zone width of a doped region with a high potential.

The body zone widths of different doped regions among the at least two doped regions are adjusted so that the different doped regions among the at least two doped regions have different potentials, which contributes to the formation of a modulated electric field with a certain potential gradient in the photodiode region, thereby increasing the speed of transmission of the photogenerated carriers.

In an embodiment of the present disclosure, the doped region with the lowest potential is located at the geometric center of the photodiode region.

In an embodiment of the present disclosure, the closer a doped region is to the doped region with the lowest potential among the at least two doped regions, the lower potential the closer doped region has. In this way, the photogenerated carriers move spontaneously to the doped region with the lowest potential.

In an embodiment of the present disclosure, the doped region with the lowest potential among the at least two doped regions is configured to gather the photogenerated carriers. In this way, the photogenerated carriers randomly distributed in the photodiode region are firstly concentrated in the doped region with the lowest potential and then transmitted to parts under gates so as to avoid problems such as excessively long paths of transmission of the photogenerated carriers and differences in transmission delays.

In an embodiment of the present disclosure, the doped regions among the at least two doped regions have potentials decreasing in the longitudinal direction.

In an embodiment of the present disclosure, the doped region with the lowest potential is connected to at least one control unit in the sensor, wherein the at least one control unit is configured to control the transmission of the photogenerated carriers between the photodiode region and at least one post-stage processing unit in the sensor.

In an embodiment of the present disclosure, the at least one post-stage processing unit is configured to convert the photogenerated carriers into electrical signals; and/or the at least one post-stage processing unit is configured to deplete the photogenerated carriers concentrated in the photodiode region.

In an embodiment of the present disclosure, the doped regions with different potentials among the at least two doped regions are arranged in a direction from the edge of the photodiode region to the geometric center of the photodiode region, wherein the at least two doped regions are arranged in the direction from the edge of the photodiode region to the geometric center of the photodiode region according to an order of potential from high to low.

In an embodiment of the present disclosure, the at least one control unit is connected to at least one post-stage processing unit via at least one storage unit in the sensor, and the at least one storage unit is configured to store the photogenerated carriers from the photodiode region.

In an embodiment of the present disclosure, at least one transmission gate is connected to at least one storage unit, and the at least one storage unit is configured to store the photogenerated carriers obtained at different time points through a channel formed when the at least one transmission gate is turned on.

In a second aspect of the embodiments of the present disclosure, a method of fabricating a photodiode is provided. The method includes: forming a photodiode region in a predetermined region of an epitaxial layer on a semiconductor substrate; forming at least two doped regions in the photodiode region, wherein doped regions with different potentials among the at least two doped regions are arranged in a direction from an edge of the photodiode region to a geometric center of the photodiode region. In an embodiment of the present disclosure, the geometric center of the photodiode region is the geometric center of a surface of the photodiode region.

In an embodiment of the present disclosure, the formation of at least two doped regions in the photodiode region includes: forming different doped regions with different doping concentrations in the photodiode region; and/or, forming different doped regions with different body zone widths in the photodiode region.

In an embodiment of the present disclosure, the doped region with the lowest potential is located at the geometric center of the photodiode region.

In an embodiment of the present disclosure, wherein the closer a doped region is to the doped region with the lowest potential among the at least two doped regions, the lower potential the closer doped region has.

In an embodiment of the present disclosure, the doped region with the lowest potential among the at least two doped regions is configured such that the photogenerated carriers are concentrated therein.

In an embodiment of the present disclosure, the doped regions among the at least two doped regions have potentials decreasing in the longitudinal direction.

In an embodiment of the present disclosure, the method further includes: forming at least one control unit on the doped region with the lowest potential. Here, the at least one control unit is configured to control the transmission between the photodiode region and at least one post-stage processing unit in the sensor.

Correspondingly, in an embodiment of the present disclosure, the at least one post-stage processing unit is configured to convert the photogenerated carriers into electrical signals; and/or the at least one post-stage processing unit is configured to deplete the photogenerated carriers from the photodiode region.

In an embodiment of the present disclosure, the arrangement of doped regions with different potentials among the at least two doped regions from the edge of the photodiode region to the geometric center of the photodiode region includes: an arrangement of the at least two doped regions from the edge of the photodiode region to the geometric center of the photodiode region in descending order of potential.

In an embodiment of the present disclosure, the formation of different doped regions with different doping concentrations in the photodiode region includes: injecting a doping material into at least two regions in a preset range of the photodiode region according to preset times of injection, to form the at least two doped regions; or injecting a doping material at different concentrations into at least two regions in a preset range of the photodiode region to form the at least two doped regions; or injecting a doping material into at least two regions in a preset range of the photodiode region using masks with different perforation densities, to form the at least two doped regions.

In an embodiment of the present disclosure, the injection of a doping material into at least two regions in a preset range of the photodiode region according to a preset number of times of injections comprises situations where the doping material injected into the at least two regions comprises an N-type material, the closer a region among the at least two regions is to the geometric center, the more times the N-type material will be injected into its corresponding closer region, a region performed with more times of injections will form a lower potential in a doped region; or where the doping material injected into the at least two regions comprises a P-type material, the farther a region among the at least two regions is from the geometric center, the more times the P-type material will be injected into its corresponding farther region, a region performed with more times of injections will form a higher potential in a doped region; or where the doping material injected into the at least two regions comprises an N-type material and a P-type material, the farther a region among the at least two regions is from the geometric center, the more times the P-type material will be injected into its corresponding farther region will be performed, a region performed with more times of injections of P-type material will form a higher potential in a doped region; or where the doping material injected into the at least two regions comprises an N-type material and a P-type material, the closer a region among the at least two regions is to the geometric center, the more times the N-type material will be injected into its corresponding closer region, a region performed with more times of injections of N-type material will form a lower potential in a doped region.

In an embodiment of the present disclosure, at least two regions in a preset range of the photodiode region are injected with a doping material at different concentrations; where the doping material injected into the at least two regions comprises an N-type material, the closer a region among the at least two regions is to the geometric center, the higher a concentration of the closer region will be, a region with a higher concentration will form a lower potential in a doped region; or where the doping material injected into the at least two regions comprises a P-type material, the farther a region among the at least two regions is from the geometric center, the higher a concentration of the farther region will be, a region with a higher concentration will form a higher potential in a doped region; or where the doping material injected into the at least two regions comprises an N-type material and a P-type material, the farther a region among the at least two regions is from the geometric center, the higher a concentration of the P-type material in the farther region will be, a region with a higher concentration of P-type material will form a higher potential in a doped region; or where the doping material injected into the at least two regions comprises an N-type material and a P-type material, the closer a region among the at least two regions is to the geometric center, the higher a concentration of the N-type material in the closer region will be, a region with a higher concentration of N-type material will form a lower potential in a doped region.

In an embodiment of the present disclosure, the formation of different doped regions with different body zone widths in the photodiode region includes: forming different doped regions with an identical concentration of a doping material, where a doped region with a larger body zone width has a lower potential.

In an embodiment of the present disclosure, the method further includes: forming at least one storage unit between the at least one control unit and the at least one post-stage processing unit in the sensor. Here, the at least one storage unit is configured to store the photogenerated carriers from the photodiode region.

In an embodiment of the present disclosure, at least one transmission gate is connected to at least one storage unit, and the at least one storage unit is configured to store the photogenerated carrier obtained at different moments through a channel formed when the at least one transmission gate is turned on.

In a third aspect of the embodiments of the present disclosure, a CMOS sensor is provided. The CMOS sensor includes: a semiconductor substrate; an epitaxial layer formed on the semiconductor substrate; a photodiode region formed in a predetermined region of the epitaxial layer and configured to generate photogenerated carriers, the photodiode region including at least two doped regions, doped regions with different potentials among the at least two doped regions being arranged in a direction from the edge of the photodiode region to the geometric center of the photodiode region; at least one control unit connected to a doped region with the lowest potential among the at least two doped regions and configured to control transmission of the photogenerated carriers between the photodiode region and at least one post-stage processing unit; and the at least one post-stage processing unit configured to convert the photogenerated carriers into electrical signals, and/or configured to deplete the photogenerated carriers from the photodiode region. Here, the structure of the photodiode region is the same as that of any photodiode region as described in the first aspect.

In a fourth aspect of the embodiments of the present disclosure, a sensor is provided. The sensor includes: a photodiode region configured to receive echo radiation reflected by an object to be measured, formed in a predetermined region of an epitaxial layer on a semiconductor substrate, and configured to generate photogenerated carriers based on the received echo radiation, the photodiode region including at least two doped regions, doped regions with different potentials among the at least two doped regions being arranged in a direction from the edge of the photodiode region to the geometric center of the photodiode region; at least one control unit connected to a doped region with the lowest potential among the at least two doped regions and configured to control transmission of the photogenerated carriers from the photodiode region to at least one post-stage processing unit according to a preset demodulation frequency; and the at least one post-stage processing unit configured to convert the photogenerated carriers into electrical signals and/or, to deplete the photogenerated carriers concentrated in the photodiode region. Here, the structure of the photodiode region is the same as that of any photodiode region as described in the first aspect.

In a fifth aspect of the embodiments of the present disclosure, a sensor array is provided. The sensor array includes a plurality of sensors. The plurality of sensors may be the same as a plurality of any CMOS sensor as described in the fourth aspect, or, the plurality of sensors may be the same as a plurality of any sensor as described in the fifth aspect. Here, the structure of the photodiode region included in the sensor is the same as that of any photodiode region as described in the first aspect.

In the technical solutions of the present disclosure, the photogenerated carriers are attracted to move along the direction towards the geometric center of the photodiode region from the edge of the photodiode region, so that the photogenerated carriers randomly distributed in the photodiode region are firstly concentrated in a specified position and then transferred to transmission gates from the specified position, thereby avoiding systematic errors resulting from different transmission delays caused by these randomly distributed photogenerated carriers travelling different paths to reach different transmission gates. This contributes to an improved measurement precision of a sensor based on the photodiode. Also, this avoids a long transmission delay caused by a long distance from some photogenerated carriers to the transmission gates. This helps shorten the delay of transmission of the photogenerated carriers to parts under the gates and increase the speed of transmission of the photogenerated carriers and the response speed of the sensor.

### BRIEF DESCRIPTION OF THE DRAWINGS

FIG. 1 schematically shows a schematic structural diagram of a photodiode in the prior art;

FIG. 2 schematically shows a schematic structural diagram of a ranging scenario to which an embodiment of the present disclosure is applicable;

FIG. 3A schematically shows a side sectional view of a photodiode according to an embodiment of the present disclosure;

FIG. 3B schematically shows a side sectional view of another photodiode according to an embodiment of the present disclosure;

FIG. 3C schematically shows a side sectional view of a clamp photodiode according to an embodiment of the present disclosure;

FIG. 3D schematically shows a side sectional view of another clamp photodiode according to an embodiment of the present disclosure;

FIG. 4A schematically shows a top view of a photodiode according to an embodiment of the present disclosure;

FIG. 4B schematically shows a top view of another photodiode according to an embodiment of the present disclosure;

FIG. 5 schematically shows a schematic diagram of a tendency of a change in potential in a photodiode according to an embodiment of the present disclosure;

FIG. 6 schematically shows a schematic structural diagram of an equivalent circuit of a photodiode-based sensing unit according to an embodiment of the present disclosure;

FIG. 7 schematically shows a schematic flowchart of a method for fabricating a photodiode according to an embodiment of the present disclosure;

FIG. 8 schematically shows a schematic structural diagram of a sensor according to an embodiment of the present disclosure; and

FIG. 9 schematically shows a schematic structural diagram of a sensor array according to an embodiment of the present disclosure.

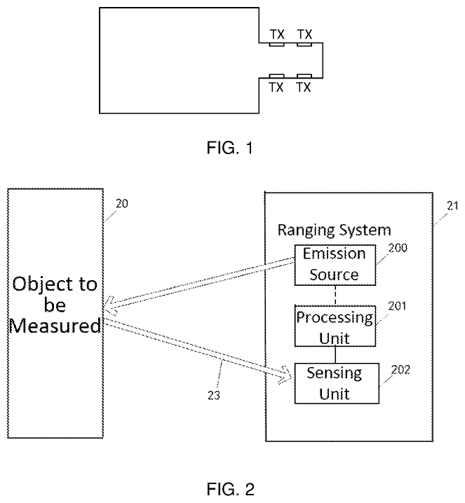

### DETAILED DESCRIPTION OF THE EMBODIMENTS

The present disclosure will be described below in further detail with reference to the accompanying drawings in order to further clarify the objects, technical solutions, and advantages of the present disclosure. It is apparent that the embodiments to be described are some, but not all of the embodiments of the present disclosure. All the other embodiments obtained by those of ordinary skill in the art in light of the embodiments of the present disclosure without inventive efforts will fall within the scope of the present disclosure as claimed.

The inventor has found that, in a current prior art photodiode structure, the uniform distribution of photogenerated carriers causes zero change to a transverse potential in a photodiode, which renders absence of effective electric field in the photodiode and hence gives rise to the photogenerated carriers travelling by diffusion movement at a low speed. Therefore, the CMOS sensors based on the prior art photodiode structures are far from satisfying the requirements for CMOS sensors in measuring long distance with high precision.

In view of the above-mentioned problems, the present disclosure provides a photodiode, a method of fabricating the same, a sensor, and a sensor array. A photodiode includes: a semiconductor substrate; an epitaxial layer formed on the semiconductor substrate; and a photodiode region formed in a predetermined region of the epitaxial layer and configured to generate photogenerated carriers. The photodiode region includes at least two doped regions. Doped regions with different potentials among the at least two doped regions are arranged in a direction from the edge of the photodiode region to the geometric center of the photodiode region. In the present disclosure, the photogenerated carriers are attracted to move along the direction towards the geometric center of the photodiode region from the edge of the photodiode region, so that the photogenerated carriers randomly distributed in the photodiode region are firstly concentrated in a specified position and then transferred to transmission gates from the specified position, thereby avoiding systematic errors resulting from different transmission delays caused by these randomly distributed photogenerated carriers travelling different paths to reach different transmission gates. This contributes to an improved measurement precision of a sensor. Also, this avoids a longer transmission delay resulting from some photogenerated carriers are farther from the transmission gates than other photogenerated carriers. This helps shorten the delay of transmission of the photogenerated carriers to parts under the gates and increase the speed of transmission of the photogenerated carriers and the response speed of the sensor. After the basic principles of the present disclosure are discussed, various non-limiting embodiments of the present disclosure will be specifically discussed below.

The embodiments of the present disclosure are applicable to a ranging scenario, especially a long-distance ranging scenario requiring high-precision. Referring to FIG. 2, a ranging scenario involved in an embodiment of the present disclosure includes at least a ranging system 20 and an object 21 to be measured. The ranging system 20 involved in the embodiment of the present disclosure includes, but is not limited to, an emission source 200, a processing unit 201, and a sensing unit 202. Optionally, the emission source 200, the processing unit 201, and the sensing unit 202 may be arranged in the same device or in different devices, which is not limited here. Here, the sensing unit 202 includes, but is not limited to, a photodiode region, at least one control unit, and at least one post-stage processing unit. The photodiode region is configured to receive echo radiation reflected by the object to be measured and generate photogenerated carriers based on the echo radiation. The photodiode region includes at least two doped regions. Doped regions with different potentials among the at least two doped regions are arranged in a direction from the edge to the geometric center of the photodiode region. The at least one control unit is connected to a doped region with the lowest potential among the at least two doped regions and is configured to control the transmission of the photogenerated carriers from the photodiode region to at least one post-stage processing unit according to a preset demodulation frequency. The at least one post-stage processing unit is configured to convert photogenerated carriers into electrical signals, and/or configured to deplete the photogenerated carriers concentrated in the photodiode region. The ranging system 20 operates based on the following principle. The processing unit 201 controls the emission source 200 to form a modulation signal and emit modulated radiation 23 based on a modulation frequency. The emission source 200 includes, but is not limited to, a laser emission source, an LED, or an LED array consisting of multiple LEDs. The modulation signal includes, but is not limited to, a pseudo-random signal, such as a GOLD signal in a pseudo-random signal. The radiation 23 emitted from the emission source 200 includes, but is not limited to, laser light, monochromatic light, and the like. The radiation 23 is reflected or diffusely reflected to the ranging system 20 by the object 21 to be measured. After the ranging system 20 receives the radiation 23 by means of the sensing unit 202, the sensing unit 202 is controlled by the processing unit 201 to form a modulation signal for receiving the radiation 23 and receive the radiation 23 through the modulation signal to generate photogenerated carriers. Optionally, the sensing unit 202 may be at least one sensor or at least one sensor array. Optionally, the geometric center of the photodiode region is the geometric center of a surface of the photodiode region.

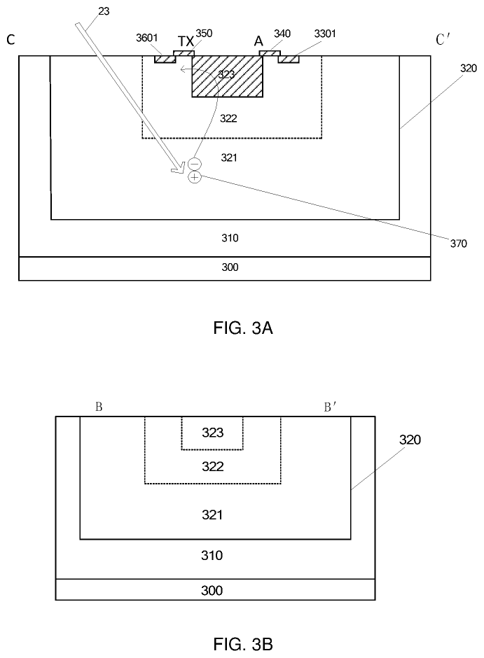

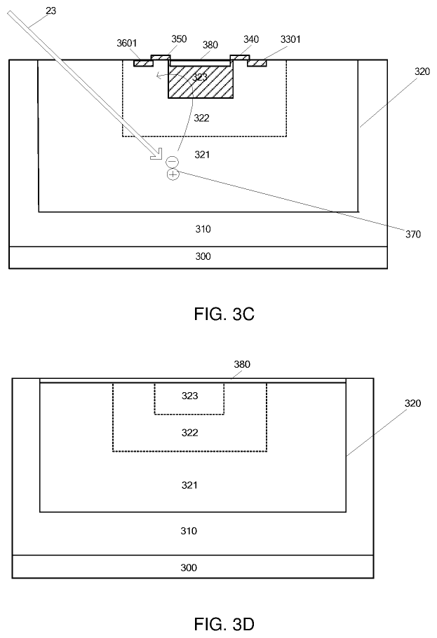

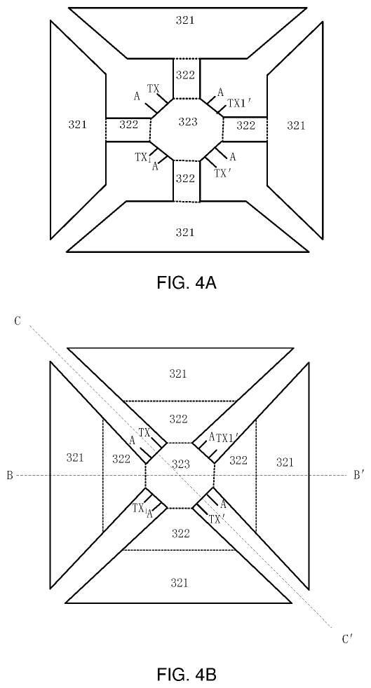

A photodiode according to an exemplary embodiment of the present disclosure is described below in connection with the application scenario of FIG. 2 with reference to FIG. 3A. FIG. 3A is a side sectional view of the photodiode, and FIG. 3B is another side sectional view of the photodiode. It should be noted that FIG. 3A is taken along a cutting line C-C′ of a top view shown in FIG. 4B in a not-to-scale manner, and FIG. 3B is taken along a cutting line B-B′ of the top view shown in FIG. 4B in a not-to-scale manner. FIG. 3C is a side sectional view of a clamp photodiode, and FIG. 3D is another side sectional view of a clamp photodiode. Optionally, a clamping layer 380 is arranged in the photodiode region. It should be understood that a photodiode involved in an embodiment of the present disclosure may be in a front-illuminated form, or in a back-illuminated form, or in a stacked or other form, which is not limited in the embodiment of the present disclosure. For example, the photodiodes shown in FIGS. 3A and 3C are front-illuminated. The above-mentioned application scenario is shown only for the purpose of facilitating the understanding of the spirit and principle of the present disclosure, and the embodiments of the present disclosure are not limited in this respect. On the contrary, the embodiments of the present disclosure can be applied to any applicable scenarios.

A photodiode according to an embodiment of the present disclosure is described below by taking a front-illuminated photodiode as an example. As shown in FIG. 3A, the photodiode includes a semiconductor substrate 300, an epitaxial layer 310, and a photodiode region 320. Here, the epitaxial layer 310 is formed on the semiconductor substrate 300, and the photodiode region 320 is formed in a predetermined region of the epitaxial layer 310. The photodiode region 320 is formed in a predetermined region of the epitaxial layer 310. The photodiode region 320 is configured to generate photogenerated carriers. The photodiode region 320 includes at least two doped regions. Doped regions with different potentials among the at least two doped regions are arranged in a direction from the edge of the photodiode region to the geometric center of the photodiode region, therefore a multi-stage modulated electric field is formed between the doped regions with different potentials, which leads to the photogenerated carriers moving toward the geometric center of the photodiode region under the action of the multi-stage modulated electric field, and the photogenerated carriers are thus concentrated in a specified position of the photodiode region. Optionally, the geometric center of the photodiode region is the geometric center of a surface of the photodiode region.

In an embodiment, the geometric center of the photodiode region may refer to the geometric center of a surface of the photodiode region connected to a passivation layer. The passivation layer refers to an insulating material covering the surface of a semiconductor material, that is, an insulating material covering the surface of the photodiode region. The insulating material includes, but is not limited to, silicon dioxide, silicon nitride, and the like. The passivation layer is configured to passivate defects on the surface of the photodiode region so as to protect the surface of the photodiode region and avoid damage to the surface of the photodiode region caused by high-energy ions during ion implantation. In another embodiment, the geometric center of the photodiode region may refer to the geometric center of a surface of the photodiode region connected to a P-type material layer.

It can be seen from the above description that in the photodiode according to the embodiment of the present disclosure, the photogenerated carriers are attracted to move along the direction towards the geometric center of the photodiode region 320 from the edge of the photodiode region, so that the photogenerated carriers randomly distributed in the photodiode region 320 are firstly concentrated in a specified position and then transferred to transmission gates from the specified position, thereby avoiding systematic errors resulting from different transmission delays caused by these randomly distributed photogenerated carriers travelling different paths to the transmission gates. This contributes to an improved measurement precision of a sensor. Also, this avoids a long transmission delay resulting from some photogenerated carriers are farther from the transmission gates than other photogenerated carriers. This helps shorten the delay of transmission of the photogenerated carriers to parts under the gates and increase the speed of transmission of the photogenerated carriers and the response speed of the sensor.

The shape of the predetermined region may be a geometric figure symmetric about the geometric center, or other figure, which is not limited in the embodiment of the present disclosure. For example, the shape of the predetermined region may be one of two special-shaped structures as shown in FIGS. 4A and 4B. Correspondingly, the at least two doped regions may be arranged in multiple modes. In one of the multiple arrangement modes, the at least two doped regions may be arranged in the direction from the edge of the photodiode region to the geometric center of the photodiode region according to an order of potential from high to low (i.e., a first arrangement mode). In another possible mode, the at least two doped regions may be arranged in the direction from the edge of the photodiode region to the geometric center of the photodiode region according to an order of potential from low to high (i.e., a second arrangement mode).

Taking FIG. 4B as an example, four doped regions 321, four doped regions 322, and one doped region 323 are arranged in a direction from the edge of the photodiode region to the geometric center of the photodiode region according to an order of potential from high to low, where the doped regions 323 has the lowest potential. It should be noted that there may be one or more doped regions 321 and one or more doped regions 322, and the numbers shown in this example are only exemplary and are not limited in the embodiment of the present disclosure. For another example, a plurality of doped regions 401 are connected to the same doped region 402, the potentials of the doped regions 401 are higher than the potential of the doped region 402, and the doped region 402 has the lowest potential. For another example, a plurality of doped regions 403 surround a doped region 404, and the potentials of the doped regions 403 are higher than the potential of the doped region 404.

A photodiode region 320 including three doped regions is taken as an example. The three doped regions are arranged in a direction from the edge to the geometric center of the photodiode region according to an order of potential from high to low. The three doped regions are a first doped region 321, a second doped region 322, and a third doped region 323 in an order of potential from high to low, so that a dual-stage modulated electric field is formed between the three doped regions.

For ease of description, the first arrangement mode will be taken as an example below to illustrate related features and operating principles of a photodiode according to an embodiment of the present disclosure.

In the embodiment of the present disclosure, a doped region with the lowest potential among the at least two doped regions is configured to gather the photogenerated carriers, so that the photogenerated carriers randomly distributed in the photodiode region are firstly concentrated in the doped region with the lowest potential and then transmitted to parts under gates so as to avoid problems such as excessively long paths of transmission of the photogenerated carriers and differences in transmission delays. Optionally, the doped region with the lowest potential is located at the geometric center of the photodiode region 320. It should be noted that the doped region with the lowest potential may be located at a position in the photodiode region 320 other than the geometric center of the photodiode region 320, which is not limited here.

Correspondingly, the closer a doped region is to the doped region with the lowest potential among the at least two doped regions, the lower potential the closer doped region has. This contributes to spontaneous movement of the photogenerated carriers to the doped region with the lowest potential. Optionally, different doped regions among the at least two doped regions have potentials decreasing in a longitudinal direction, which contributes to the spontaneous movement of the photogenerated carriers to the doped region with the lowest potential in the longitudinal direction. In one embodiment, the potentials of the different doped regions among the at least two doped regions decrease in the longitudinal direction from one side surface to the other side surface of the photodiode region.

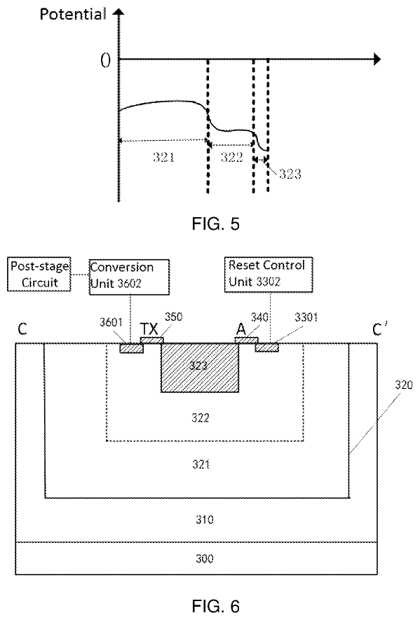

Specifically, in the direction from the edge to the geometric center of the photodiode region 320, the potentials of the different doped regions among the at least two doped regions may decrease smoothly, or decrease stepwise or in other form, which is not limited in the embodiment of the present disclosure. Taking the photodiode region 320 shown in FIG. 3A as an example, the potential of the photodiode region 320 may have a tendency to change in the direction from the first doped region 321 to the third doped region 323 in the form of an exemplary curve as shown in FIG. 5.

The doped region with the lowest potential among the at least two doped regions is connected to at least one control unit in a sensor. Here, the at least one control unit is configured to control the transmission of photogenerated carriers between the photodiode region and at least one post-stage processing unit in the sensor. The at least one control unit includes, but is not limited to, a transmission gate, a reset control gate, a drift gate, a modulation gate, and a storage gate. Optionally, the sensor includes a plurality of control units. The plurality of control units are configured to transmit the photogenerated carriers generated by the photodiode region receiving radiation at different moments to at least one post-stage processing unit.

The at least one control unit in the sensor is connected to at least one post-stage processing unit, respectively. Here, the at least one post-stage processing unit may be configured to convert the photogenerated carriers into electrical signals. The at least one post-stage processing unit includes, but is not limited to, a storage unit, a reading unit, a conversion unit, a floating diffusion node (FD), and a post-stage circuit. Specifically, upon the transmission of the photogenerated carriers generated by the photodiode region receiving radiation at different moments to at least one post-stage processing unit, a plurality of storage units corresponding to the plurality of control units store the respective received photogenerated carriers, and the photogenerated carriers stored in the plurality of storage units are converted into multiple electrical signals by a conversion unit corresponding to the plurality of storage units, so that the sensor can achieve a ranging function through subsequently processing the multiple electrical signals, especially in scenario where measuring a long distance with high precision is in need; The at least one post-stage processing unit may be also configured to deplete the photogenerated carriers concentrated in the photodiode region. The at least one post-stage processing unit includes, but is not limited to, a storage unit and a reset control unit. Optionally, the at least one control unit is connected to at least one post-stage processing unit via at least one storage unit in the sensor. The at least one storage unit is configured to store the photogenerated carriers from the photodiode region. Specifically, at least one transmission gate is connected to at least one storage unit, and the at least one storage unit is configured to store photogenerated carriers obtained at different moments through a channel formed when at least one transmission gate is turned on.

Based on the structure of the photodiode region 320 shown in FIG. 3A and related structures, the photodiode shown in FIG. 3A operates based on the following principle. The photodiode region 320 receives radiation 23 to generate photogenerated carriers. In other words, the three doped regions receive radiation 23 to generate photogenerated carriers. Photogenerated carriers generated in the first doped region 321 are taken as an example to illustrate the direction of movement of the photogenerated carriers. Assuming that the photogenerated carriers are photoelectron-hole pairs 370, the photoelectrons are moved towards the geometric center of the diode region 320 under the action of the two-stage modulated electric field. The photoelectrons randomly distributed in the first doped region 321 and in the second doped region 322 are concentrated in the third doped region 323. The photoelectrons concentrated in the third doped region 323 are moved from the third doped region 323 to parts under gates when the control unit is turned on, where the control unit includes a transmission gate 350 and a reset control gate 340. The transmission gate 350 is connected to a storage unit 3601 included in the parts under gates. The storage unit 3601 is configured to store the photogenerated carriers generated by the photodiode region 320. The reset control gate 340 is connected to a storage unit 3301 included in the parts under gates. The storage unit 3301 is configured to be connected to its post-stage processing unit within a preset time period or at a preset moment to deplete the photogenerated carriers concentrated in the photodiode region.

FIG. 6 shows an equivalent circuit diagram of a sensing unit composed of the structure of a photodiode region 320 and related structures, where the control unit includes a transmission gate 350 and a reset control gate 340, and the post-stage processing unit includes a storage unit 3301, a reset control unit 3302, a storage unit 3601, a conversion unit 3602, and the post-stage circuit. 0Referring to FIG. 6, the equivalent circuit diagram is operated based on the following principle. The photodiode region 320 receives radiation to generate randomly distributed photogenerated carriers. These randomly distributed photogenerated carriers are moved towards the geometric center of the photodiode region 320 under the action of a multi-stage modulated electric field, so that these randomly distributed photogenerated carriers are concentrated in the doped region with the lowest potential. When the transmission gate 350 is turned on, these photogenerated carriers are transmitted from the doped region with the lowest potential, through a channel formed under the transmission gate 350, to the storage unit 3601 and stored in the storage unit 3601. Then, the photogenerated carriers stored in the storage unit 3601 are converted into electrical signals by the conversion unit 3602, and the electrical signals are transmitted to the post-stage circuit. When the reset control gate 340 and the reset control unit 3302 are turned on, the photodiode region 320 and the storage unit 3301 are reset. And the photogenerated carriers in the photodiode region 320 and in the storage unit 3301 are depleted by the reset control unit 3302.

In an embodiment of the present disclosure, there are at least two doped regions with different potentials in the photodiode region. Specifically, the at least two doped regions with different potentials have one or a combination of the following characteristics.

As a first characteristic, different doped regions among the at least two doped regions have different body zone widths.

A narrowing of the body zone width of a doped region may induce an effect of crowding of electrons at the edge, resulting in an increased potential of the doped region. When doping materials sharing the same concentration, the potentials of different doped regions are mainly affected by body zone widths of the different doped regions; when the doping materials having different concentrations, the potentials of different doped regions are affected by the body zone width and the concentration of the doping material. For ease of description, the first characteristic is described below by taking a doping material having an identical concentration as an example. Among different doped regions with the doping material having an identical concentration, a doped region with a low potential has a body zone width larger than that of the doped region with a high potential. In other words, among different doped regions where the doping material having an identical concentration, a doped region with a larger body zone width has a lower potential because the effect of crowding of electrons at the edge is more advantageously eliminated from the doped region. It should be understood that in the case where a doping material having different concentrations in a practical application, the body zone widths of the different doped regions may also be increased to eliminate the effect of crowding of electrons at the edge, so as to decrease the potentials of the doped regions.

Based on the first characteristic, the body zone widths of different doped regions among the at least two doped regions are adjusted so that the different doped regions among the at least two doped regions have different potentials, which contributes to the formation of a modulated electric field with a certain potential gradient in the photodiode region. Thus, the photogenerated carriers move from the edge to the geometric center of the photodiode region through the transverse electric field to be concentrated, thereby increasing the speed of transmission of the photogenerated carriers.

As a second characteristic, different doped regions among the at least two doped regions have different doping concentrations.

The doping concentrations of different doped regions among the at least two doped regions mainly include the following cases.

In a first case, if the at least two doped regions are N-type doped regions, it is indicated that the main doping material in the at least two doped regions is an N-type material. Since the higher the concentration of an N-type material in an N-type doped region is, the lower potential the N-type doped region has; therefore the concentration of the N-type material in a doped region with a low potential is greater than the concentration of the N-type material in a doped region with a high potential.

Optionally, the concentration of the N-type material in the doped region with a high potential may be 1E14 to 1E17, and the concentration of the N-type material in the doped region with a low potential may be 1E17 to 1E20.

In a second case, if the at least two doped regions are P-type doped regions, it is indicated that the main doping material in the at least two doped regions is a P-type material. Since the higher the concentration of a P-type material in a P-type doped region is, the higher potential the P-type doped region has; therefore the concentration of the P-type material in the doped region with a low potential is less than the concentration of the P-type material in the doped region with a high potential.

In a third case, if the at least two doped regions are N-type doped regions, it is indicated that the main doping material in the at least two doped regions is an N-type material. Since the higher the concentration of a P-type material in an N-type doped region is, the higher potential the N-type doped region has; therefore the concentration of the P-type material in the doped region with a low potential is not greater than the concentration of the P-type material in the doped region with a high potential. It should be noted that the N-type doped region may include a P-type material, but the concentration of the P-type material is much lower than that of the N-type material.

In a fourth case, if the at least two doped regions are P-type doped regions, it is indicated that the main doping material in the at least two doped regions is a P-type material. Since the higher the concentration of an N-type material in a P-type doped region is, the lower potential the P-type doped region has; therefore the concentration of the N-type material in the doped region with a high potential is not greater than the concentration of the N-type material in the doped region with a low potential. It should be noted that the P-type doped region may include an N-type material, but the concentration of the N-type material is much lower than that of the P-type material.

Based on the second characteristic, the doping concentrations in different doped regions among the at least two doped regions are adjusted so that the different doped regions among the at least two doped regions have different potentials, which contributes to the formation of a modulated electric field with a certain potential gradient in the photodiode region. Thus, the photogenerated carriers move from the edge to the geometric center of the photodiode region through the transverse electric field to be concentrated, thereby increasing the speed of transmission of the photogenerated carriers. Also, this helps eliminate an effect of crowding of electrons at the edge caused by the narrowing of the body zone width of a doped region, thereby further decreasing the potential of the doped region.

It should be noted that the type of the sensor described above may be a CMOS sensor or other type of sensor, which is not limited here.

In the photodiode according to the embodiment of the present disclosure, the photogenerated carriers are attracted to move along the direction towards the geometric center of the photodiode region from the edge of the photodiode region, so that the photogenerated carriers randomly distributed in the photodiode region are firstly concentrated in a specified position and then reach transmission gates from the specified position, thereby avoiding systematic errors resulting from different transmission delays caused by these randomly distributed photogenerated carriers travelling different paths to reach different transmission gates. This contributes to an improved measurement precision of a sensor. Also, this avoids a long transmission delay resulting from some photogenerated carriers are farther from the transmission gates than other photogenerated carriers. This helps shorten the delay of transmission of the photogenerated carriers to parts under the gates and increase the speed of transmission of the photogenerated carriers and the response speed of the sensor.

After the photodiode of an exemplary embodiment of the present disclosure is discussed, an exemplary implementation of a method for fabricating a photodiode according to the present disclosure will be discussed below.

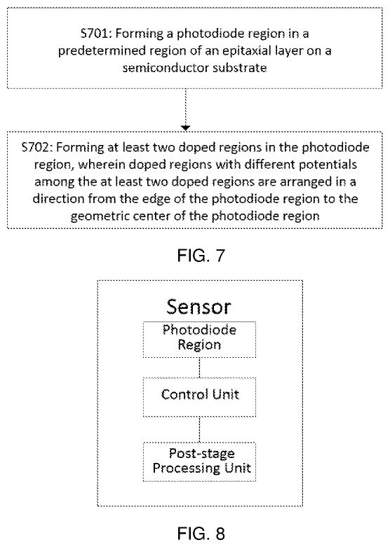

An embodiment of the present disclosure provides a method for fabricating a photodiode, as shown in FIG. 7, comprising:

S701 of forming a photodiode region in a predetermined region of an epitaxial layer on a semiconductor substrate;

S702 of forming at least two doped regions in the photodiode region, wherein doped regions with different potentials among the at least two doped regions are arranged in a direction from the edge of the photodiode region to the geometric center of the photodiode region.

Specifically, the at least two doped regions may be arranged in multiple modes. For example, in a possible arrangement mode, the at least two doped regions are arranged from the edge of the photodiode region to the geometric center of the photodiode region according to an order of potential from high to low (i.e., a first arrangement mode). In another possible arrangement mode, the at least two doped regions are arranged from the edge of the photodiode region to the geometric center of the photodiode region according to an order of potential from low to high (i.e., a second arrangement mode).

In the embodiment of the present disclosure, the photodiode may be in a front-illuminated form, in a back-illuminated form, or in a stacked or other forms, which is not limited in the embodiment of the present disclosure. For ease of description, a front-illuminated photodiode following the first arrangement mode is taken as an example below to illustrate a method for fabricating a photodiode and related features according to an embodiment of the present disclosure.

In the embodiment of the present disclosure, a doped region with the lowest potential among the at least two doped regions is configured to gather the photogenerated carriers, so that the photogenerated carriers randomly distributed in the photodiode region are firstly concentrated in the doped region with the lowest potential and then transmitted to parts under gates so as to avoid problems such as excessively long paths of transmission of the photogenerated carriers and differences in transmission delays. Correspondingly, the closer a doped region is to the doped region with the lowest potential among the at least two doped regions, the lower potential the closer doped region has, which contributes to spontaneous movement of the photogenerated carriers to the doped region with the lowest potential. Optionally, the doped region with the lowest potential is located at the geometric center of the photodiode region. The doped region with the lowest potential here is similar to that in the photodiode shown in FIG. 3A and may be understood with reference to the above related description of the photodiode shown in FIG. 3A, therefore a detailed description is omitted here.

In S701, the shape of a predetermined region is etched in the epitaxial layer on the semiconductor substrate. The shape of the predetermined region may be a geometric figure symmetric about the geometric center, or other figure, which is not limited in the embodiment of the present disclosure. For example, the shape of the predetermined region may be one of the four special-shaped structures as shown in FIGS. 4A to 4D. Methods for fabricating the semiconductor substrate and the epitaxial layer here may be implemented with reference to the methods for fabricating the substrate and the substrate epitaxial layer in the prior art, therefore a detailed description is omitted here.

An implementable method for forming at least two doped regions in S702 includes one or more of the following methods: forming different doped regions with different doping concentrations in the photodiode region (a first method); and forming different doped regions with different body zone widths in the photodiode region (a second method).

In the first method, the formation of different doped regions with different doping concentrations in the photodiode region may include the following cases.

The first method may be implemented in a possible case where a doping material is injected into at least two regions in a preset range of the photodiode region according to a preset times of injection to form the at least two doped regions. In this case, the formation of the at least two doped regions mainly includes the following modes.

In a first mode, if the doping material to be injected into the at least two regions includes an N-type material, the closer a region among the at least two regions is to the geometric center, the more times the N-type material will be injected into its corresponding closer region, a region performed with more times of injections will form a lower potential in a doped region.

In a second mode, if the doping material to be injected into the at least two regions includes a P-type material, the farther a region among the at least two regions is from the geometric center, the more times the P-type material will be injected into its corresponding farther region, a region performed with more times of injections will form a higher potential in a doped region.

In a third mode, if the doping material to be injected into the at least two regions includes an N-type material and a P-type material, the farther a region among the at least two regions is from the geometric center, the more times the P-type material will be injected into its corresponding farther region, a region performed with more times of injections of P-type material will form a higher potential in a doped region dope.

In a fourth mode, if the doping material to be injected into the at least two regions includes an N-type material and a P-type material, the closer a region among the at least two regions is to the geometric center, the more times the N-type material will be injected into its corresponding closer region, a region performed with more times of injections of N-type material will form a lower potential in a doped region.

The first method may be implemented in another possible case where a doping material is injected at different concentrations into at least two regions in a preset range of the photodiode region to form the at least two doped regions. In this case, the formation of the at least two doped regions mainly includes the following modes.

In a fifth mode, if the doping material to be injected into the at least two regions includes an N-type material, the closer a region among the at least two regions is to the geometric center, the higher a concentration of the N-type material in the closer region will be, a region with a higher concentration will form a lower potential in a doped region.

In a sixth mode, if the doping material to be injected into the at least two regions includes a P-type material, the farther a region among the at least two regions is from the geometric center, the higher a concentration of the P-type in the farther region will be, a region with a higher concentration will form a higher potential in a doped region.

In a seventh mode, if the doping material to be injected into the at least two regions includes an N-type material and a P-type material, the farther a region among the at least two regions is from the geometric center, the higher a concentration of the P-type material in the farther region will be, a region with a higher concentration of P-type material will form a higher potential in a doped region.

In an eighth mode, if the doping material to be injected into the at least two regions includes an N-type material and a P-type material, the closer a region among the at least two regions is to the geometric center, the higher a concentration of the N-type material in the closer region will be, a region with a higher concentration of N-type material will form a lower potential in a doped region.

The first method may be implemented in another possible case where a doping material is injected into at least two regions in a preset range of the photodiode region using masks with different perforation densities to form the at least two doped regions. In this case, a region where a perforation density of a mask adopted in the at least two regions is greater, the concentration of the doping material injected into the region is higher. In this case, the formation of the at least two doped regions may be specifically implemented with reference to the above related description of the corresponding relationships between the concentration of the doping material and the potential in the fifth to eighth modes of forming the at least two doped regions, therefore a detailed description is omitted here.

In the first method, the doping concentrations in different doped regions among the at least two doped regions are adjusted so that the different doped regions among the at least two doped regions have different potentials, which contributes to the formation of a modulated electric field with a certain potential gradient in the photodiode region. Thus, the photogenerated carriers are attracted to move towards the geometric center of the photodiode region from the edge of the photodiode region through the transverse electric field, hereby increasing the speed of transmission of the photogenerated carriers. Also, this helps eliminate an effect of crowding of electrons at the edge caused by the narrowing of the body zone width of a doped region, thereby further decreasing the potential of the doped region.

In a second method, different doped regions with different body zone widths are formed in the photodiode region.

Specifically, among different doped regions with an identical concentration of a doping material, a doped region with a larger body zone width has a lower potential. The body zone widths of different doped regions among the at least two doped regions are adjusted so that the different doped regions among the at least two doped regions have different potentials, which contributes to the formation of a modulated electric field with a certain potential gradient in the photodiode region. Thus, the photogenerated carriers move from the edge to the geometric center of the photodiode region through the transverse electric field, thereby increasing the speed of transmission of the photogenerated carriers.

After S702 or before S702, at least one control unit is formed on the doped region with the lowest potential. Taking at least one transmission gate as an example of the at least one control unit, a polysilicon gate is formed on an upper surface of the epitaxial layer, and the formed polysilicon gate is etched to obtain at least one transmission gate. Here, the at least one control unit is configured to control the transmission between the photodiode region and at least one post-stage processing unit in the sensor. Optionally, the at least one post-stage processing unit may be configured to convert the photogenerated carriers into electrical signals, and the at least one post-stage processing unit may be also configured to deplete the photogenerated carriers from the photodiode region. The at least one post-stage processing unit here is similar to the above-mentioned at least one post-stage processing unit and may be understood with reference to the above relevant description of the at least one post-stage processing unit, therefore a detailed description is omitted here.

After S702 or before S702, at least one storage unit is formed between at least one control unit and at least one post-stage processing unit in the sensor. Here, the at least one storage unit is configured to store the photogenerated carriers from the photodiode region. Further, the at least one transmission gate is connected to at least one storage unit, where the at least one storage unit is configured to store photogenerated carriers obtained at different time points through a channel formed when the at least one transmission gate is turned on.

After S702, a clamping layer is made in the photodiode region to form a clamp photodiode.

After a photodiode and a method for fabricating the photodiode in exemplary embodiments of the present disclosure are discussed, an exemplary implementation of a sensor according to the present disclosure will be discussed below with reference to FIG. 8. The sensor is configured to measure a distance between an object to be measured and the sensor. The sensor includes, but is not limited to, a photodiode region, at least one control unit, and at least one post-stage processing unit. Optionally, the type of the sensor may be a CMOS sensor.

Here, the photodiode region for receiving echo radiation reflected by the object to be measured is formed in a predetermined region of an epitaxial layer on a semiconductor substrate and configured to generate photogenerated carriers based on the received echo radiation. The photodiode region includes at least two doped regions. Doped regions with different potentials among the at least two doped regions are arranged in a direction from the edge of the photodiode region to the geometric center of the photodiode region. The at least one control unit is connected to a doped region with the lowest potential among the at least two doped regions and configured to control transmission of the photogenerated carriers from the photodiode region to at least one post-stage processing unit according to a preset demodulation frequency. The at least one post-stage processing unit is configured to convert the photogenerated carriers into electrical signals, or, to deplete the photogenerated carriers concentrated in the photodiode region. Optionally, the geometric center of the photodiode region is the geometric center of a surface of the photodiode region.

It should be noted that the photodiode region shown in FIG. 8 is similar to the photodiode region in the embodiment corresponding to FIG. 3A. The similar parts may be understood with reference to the related description in the embodiment corresponding to FIG. 3A, therefore a detailed description is omitted here.

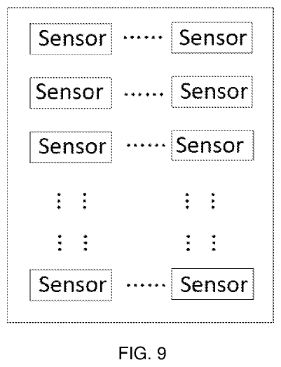

Referring to FIG. 9, the present disclosure also provides an exemplary implementation of a sensor array. The sensor array includes a plurality of sensors shown in FIG. 8, or the sensor array includes a plurality of sensing units shown in FIG. 6, or the sensor array includes a plurality of sensing units 202 shown in FIG. 2. Optionally, the sensor array may be an array with M rows and N columns, where M and N are both positive integers.

It should be appreciated by those skilled in the art that the embodiments of the present disclosure may be provided as methods, systems, or computer program products. Therefore, the present disclosure may be embodied in the form of a complete hardware embodiment, a complete software embodiment, or an embodiment combining software and hardware. Moreover, the present disclosure may be embodied in the form of a computer program product implemented on one or more computer-usable storage media (including, but not limited to, disk memories, CD-ROMs, optical memories, etc.) containing computer-usable program codes.

The present disclosure is described with reference to flowcharts and/or block diagrams of methods, devices (systems), and computer program products according to embodiments of the present disclosure. It should be understood that each process and/or block in the flowchart and/or block diagram, and the combination of processes and/or blocks in a flowchart and/or block diagram may be implemented by computer program instructions. These computer program instructions may be provided to a processor of a general-purpose computer, a special-purpose computer, an embedded processor, or other programmable data processing device to generate a machine, so that an apparatus implementing the functions specified in one process or multiple processes in the flowchart and/or one block or multiple blocks in the block diagram is produced by the instructions executed by the processor of the computer or other programmable data processing device.

These computer program instructions may also be stored in a computer-readable memory that can guide a computer or other programmable data processing device to operate in a specific manner, so that a fabricated article including the instruction apparatus is produced by the instructions stored in the computer-readable memory. The instruction apparatus implements the functions specified in one process or multiple processes in a flowchart and/or one block or multiple blocks in the block diagram.

These computer program instructions may also be loaded on a computer or other programmable data processing device, so that a series of operation steps are executed on the computer or other programmable device to produce computer-implemented processing, so as to provide steps for implementing the functions specified in one process or multiple processes in a flowchart and/or one block or multiple blocks in the block diagram by the instructions executed on the computer or other programmable device.

Although the preferred embodiments of the present disclosure have been described, those skilled in the art can make additional changes and modifications to these embodiments once they learn the basic creative concept. Therefore, the appended claims are intended to be interpreted as including the preferred embodiments and all changes and modifications falling within the scope of the present disclosure.

Obviously, those skilled in the art can make various modifications and variations to the embodiments of the present disclosure without departing from the spirit and scope of the embodiments of the present disclosure. In this way, if these modifications and variations of the embodiments of the present disclosure fall within the scope of the claims of the present disclosure and their equivalents, the present disclosure is also intended to encompass these modifications and variations.

1. A photodiode, comprising:
a semiconductor substrate;
an epitaxial layer, formed on the semiconductor substrate; and
a photodiode region, formed in a predetermined region of the epitaxial layer and configured to generate photogenerated carriers, wherein the photodiode region comprises at least two doped regions, doped regions with different potentials among the at least two doped regions are arranged in a direction from an edge of the photodiode region to a geometric center of the photodiode region.

2. The photodiode according to claim 1, wherein different doped regions among the at least two doped regions have different doping concentrations and/or, different doped regions among the at least two doped regions have different body zone widths.

3. The photodiode according to claim 1, wherein a doped region with a lowest potential is located at the geometric center of the photodiode region.

4. The photodiode according to claim 1, wherein the closer a doped region is to the doped region with the lowest potential among the at least two doped regions, the lower potential the closer doped region has.

5. The photodiode according to claim 1, wherein the doped regions with different potentials among the at least two doped regions are arranged in a direction from the edge of the photodiode region to the geometric center of the photodiode region, wherein the at least two doped regions are arranged in the direction from the edge of the photodiode region to the geometric center of the photodiode region according to an order of potential from high to low.

6. The photodiode according to claim 2, wherein in the situation that different doped regions among the at least two doped regions have different doping concentrations:
if the at least two doped regions are N-type doped regions, a concentration of an N-type material in a doped region with a low potential is greater than a concentration of the N-type material in a doped region with a high potential; or
if the at least two doped regions are P-type doped regions, a concentration of a P-type material in a doped region with a low potential is less than a concentration of the P-type material in a doped region with a high potential; or
if the at least two doped regions are N-type doped regions, a concentration of a P-type material in a doped region with a low potential is not greater than a concentration of the P-type material in a doped region with a high potential; or
if the at least two doped regions are P-type doped regions, a concentration of an N-type material in a doped region with a high potential is not greater than a concentration of the N-type material in a doped region with a low potential.

7. The photodiode according to claim 2, wherein in the situation that different doped regions among the at least two doped regions have difference body zone widths, where in different doped regions with an identical concentration of a doping material, a doped region with a low potential has a body zone width larger than a body zone width of a doped region with a high potential.

8. A method for fabricating a photodiode, comprising:
forming a photodiode region in a predetermined region of an epitaxial layer on a semiconductor substrate; and
forming at least two doped regions in the photodiode region, wherein doped regions with different potentials among the at least two doped regions are arranged in a direction from an edge of the photodiode region to a geometric center of the photodiode region.

9. The method according to claim 8, wherein the formation of the at least two doped regions formed in the photodiode region comprises:
forming different doped regions with different doping concentrations in the photodiode region; or,
forming different doped regions with different body zone widths in the photodiode region.

10. The method according to claim 8, wherein a doped region with a lowest potential is located at the geometric center of the photodiode region.

11. The method according to claim 8, wherein the closer a doped region is to the doped region with the lowest potential among the at least two doped regions, the lower potential the closer doped region has.

12. The method according to claim 8, wherein the doped regions with different potentials among the at least two doped regions are arranged in a direction from the edge of the photodiode region to the geometric center of the photodiode region, wherein the at least two doped regions are arranged in the direction from the edge of the photodiode region to the geometric center of the photodiode region according to an order of potential from high to low.

13. The method according to claim 9, wherein the formation of different doped regions with different doping concentrations in the photodiode region comprises:
injecting a doping material into at least two regions in a preset range of the photodiode region according to a preset number of times of injections, to form the at least two doped regions; or
injecting a doping material at different concentrations into at least two regions in a preset range of the photodiode region, to form the at least two doped regions; or
injecting a doping material into at least two regions in a preset range of the photodiode region using masks with different perforation densities, to form the at least two doped regions.

14. The method according to claim 13, wherein the injection of a doping material into at least two regions in a preset range of the photodiode region according to a preset number of times of injections comprises:
where the doping material injected into the at least two regions comprises an N-type material, the closer a region among the at least two regions is to the geometric center, the more times the N-type material will be injected into its corresponding closer region; a region performed with more times of injections will form a lower potential in a doped region; or
where the doping material injected into the at least two regions comprises a P-type material, the farther a region among the at least two regions is from the geometric center, the more times the P-type material will be injected into its corresponding farther region, a region performed with more times of injections will form a higher potential in a doped region; or
where the doping material injected into the at least two regions comprises an N-type material and a P-type material, the farther a region among the at least two regions is from the geometric center, the more times the P-type material will be injected into its corresponding farther region will be performed, a region performed with more times of injections of P-type material will form a higher potential in a doped region; or
where the doping material injected into the at least two regions comprises an N-type material and a P-type material, the closer a region among the at least two regions is to the geometric center, the more times the N-type material will be injected into its corresponding closer region, a region performed with more times of injections of N-type material will form a lower potential in a doped region.

15. The method according to claim 13, wherein at least two regions in a preset range of the photodiode region are injected with a doping material at different concentrations;
where the doping material injected into the at least two regions comprises an N-type material, the closer a region among the at least two regions is to the geometric center, the higher a concentration of the closer region will be, a region with a higher concentration will form a lower potential in a doped region; or
where the doping material injected into the at least two regions comprises a P-type material, the farther a region among the at least two regions is from the geometric center, the higher a concentration of the farther region will be, a region with a higher concentration will form a higher potential in a doped region; or
where the doping material injected into the at least two regions comprises an N-type material and a P-type material, the farther a region among the at least two regions is from the geometric center, the higher a concentration of the P-type material in the farther region will be, a region with a higher concentration of P-type material will form a higher potential in a doped region; or
where the doping material injected into the at least two regions comprises an N-type material and a P-type material, the closer a region among the at least two regions is to the geometric center, the higher a concentration of the N-type material in the closer region will be, a region with a higher concentration of N-type material will form a lower potential in a doped region.

16. The method according to claim 8, wherein different doped regions with different body zone widths are formed in the photodiode region; where in different doped regions with an identical concentration of a doping material, the larger a body zone width of a doped region is, the lower a potential of the doped region will be.

17. (canceled)

18. A sensor, wherein the sensor is applicable to measure a distance between an object to be measured and the sensor, wherein the sensor comprises a photodiode region which is the photodiode region according to claim 1, wherein the sensor comprises:
the photodiode region, configured to receive echo radiation reflected by the object to be measured, wherein the photodiode region is formed in a predetermined region of the epitaxial layer on the semiconductor substrate, and configured to generate photogenerated carriers based on a received echo radiation, wherein the photodiode region comprises at least two doped regions, and doped regions with different potentials among the at least two doped regions are arranged in a direction from the edge of the photodiode region to the geometric center of the photodiode region;
at least one control unit, connected to a doped region with a lowest potential among the at least two doped regions and configured to control transmission of the photogenerated carriers from the photodiode region to at least one post-stage processing unit according to a preset demodulation frequency; and
the at least one post-stage processing unit, configured to convert the photogenerated carriers into an electrical signal and/or, to deplete the photogenerated carriers concentrated in the photodiode region.

19. (canceled)

20. The photodiode according to claim 2, wherein a doped region with a lowest potential is located at the geometric center of the photodiode region.

21. The photodiode according to claim 2, wherein a doped region closer to the doped region with the lowest potential among the at least two doped regions has a lower potential.

22. The photodiode according to claim 2, wherein an arrangement of the doped regions with different potentials among the at least two doped regions from the edge of the photodiode region to the geometric center of the photodiode region comprises:
an arrangement of the at least two doped regions from the edge of the photodiode region to the geometric center of the photodiode region in descending order of potential.
